(19) United States
(12) Patent Application Publication
(10) Pub. No.: US 2016/0099257 A1
(43) Pub. Date: Apr. 7, 2016

(54) THIN FILM TRANSISTOR AND METHOD OF MANUFACTURING THE SAME

(71) Applicant: Samsung Display Co., Ltd., Yongin-city (KR)

(72) Inventors: Donghwan Shim, Yongin-city (KR); Suyeon Sim, Yongin-city (KR); Seunghwan Cho, Yongin-city (KR); Sungeun Lee, Yongin-city (KR); Jungkyu Lee, Yongin-city (KR)

(21) Appl. No.: 14/709,844

(22) Filed: May 12, 2015

(30) Foreign Application Priority Data
Oct. 7, 2014 (KR) 10-2014-0135117

(51) Int. Cl. H01L 27/12; H01L 29/66; H01L 29/786

(52) U.S. Cl. CPC H01L 27/124; H01L 29/7869; H01L 29/78675; H01L 29/66969; H01L 29/66757; H01L 27/1259; H01L 29/78606

(57) ABSTRACT

A thin film transistor includes an active pattern formed on a substrate; a gate pattern formed on the active pattern and comprising a gate electrode and a gate line; a gate insulating layer disposed between the gate pattern and the active pattern; a source electrode that overlaps a first side of the active pattern and contacts a data line; a drain electrode that overlaps a second side of the active pattern and is separated from the source electrode; a channel area formed in an area where the gate line and an active line of the active pattern overlap each other; and a gate line modifying unit formed in the channel area by changing a linear shape of the gate line.

### CROSS-REFERENCE TO RELATED APPLICATIONS

This application claims priority to, and the benefit of, Korean Patent Application No. 10-2014-0135117, filed on Oct. 7, 2014, in the Korean Intellectual Property Office, the disclosure of which is incorporated herein in its entirety by reference.

### BACKGROUND

1. Field

One or more embodiments relate to a thin film transistor and a method of manufacturing the same.

2. Description of the Related Technology

A flat panel display apparatus, such as an organic light-emitting display apparatus or a liquid crystal display, generally includes a thin film transistor (TFT), a capacitor, and wirings that connect the TFT and the capacitor.

The wiring may include gate wirings and active wirings. An on-current value of the TFT may be determined based on a channel area that is formed by overlapping the gate wirings and the active wirings.

### SUMMARY OF CERTAIN INVENTIVE ASPECTS

One or more embodiments include a thin film transistor and a method of manufacturing the same.

Additional aspects will be set forth in part in the description which follows and, in part, will be apparent from the description, or may be learned by practice of the presented embodiments.

According to one or more embodiments, a thin film transistor (TFT) includes an active pattern formed on a substrate; a gate pattern formed on the active pattern and including a gate electrode and a gate line; a gate insulating layer disposed between the gate pattern and the active pattern; a source electrode that overlaps a first side of the active pattern and contacts a data line; a drain electrode that overlaps a second side of the active pattern and is separated from the source electrode; a channel area formed in an area where the gate line and an active line of the active pattern overlap each other; and a gate line modifying unit formed in the channel area by changing a linear shape of the gate line.

The TFT may further include a protection layer formed on the source and drain electrodes.

The TFT may further include a pixel electrode formed in an upper portion of the protection layer and contacting the drain electrode via a contact hole.

The gate line modifying unit may have a “U” shape.

The gate line modifying unit may have a “V” shape.

A width of the active line may be reduced such that a size of the channel area is the same a gate line having a linear shape.

The gate line changing unit may be further formed at an end of the gate line.

According to one or more embodiments, a method of manufacturing a TFT includes forming an active pattern on a substrate, the active pattern including an active layer and an active line; depositing a gate insulating layer on the active pattern; forming a gate pattern on the gate insulating layer, the gate pattern including a gate electrode and a gate line; and forming a source pattern and a drain pattern on the substrate. A channel area is formed at an area where the gate line and the active line overlap each other, and a gate line modifying unit is formed by changing a linear shape of the gate line at the channel area.

The gate line modifying unit may have a “U” shape.

The gate line modifying unit may have a “V” shape.

The method may further comprise forming a source electrode that overlaps a first side of the active pattern and contacts a data line.

The method may further comprise forming a drain electrode that overlaps a second side of the active pattern and is separated from the source electrode;

The method may further comprise forming a protection layer on the source and drain electrodes.

The method may further comprise forming a pixel electrode formed in an upper portion of the protection layer and contacting the drain electrode via a contact hole.

A width of the active line may be reduced such that a size of the channel area is the same as a gate line having a linear shape.

According to one or more embodiments, a thin film transistor (TFT) includes: an active pattern formed on a substrate; a gate pattern formed on the active pattern and comprising a gate electrode and a gate line; a gate insulating layer disposed between the gate pattern and the active pattern; a channel area formed in an area where the gate line and the active line overlap each other; and a gate line modifying unit formed in the channel area by changing a linear shape of the gate line.

The TFT may further include: a source electrode that overlaps a first side of the active pattern and contacts a data line; and a drain electrode that overlaps a second side of the active pattern and is separated from the source electrode.

The TFT may further include: a protection layer formed on the source and drain electrodes; and a pixel electrode formed in an upper portion of the protection layer and contacting the drain electrode via a contact hole.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic wiring diagram according to an embodiment;

FIG. 2 is a schematic cross-sectional view of a thin film transistor according to an embodiment;

FIG. 3 is a schematic wiring diagram according to an embodiment;

FIG. 4A is a schematic diagram of a gate line and an active line of the related art; and

FIG. 4B is a schematic diagram of a gate line and an active line according to an embodiment.

### DETAILED DESCRIPTION OF CERTAIN INVENTIVE EMBODIMENTS

As the inventive concept allows for various changes and numerous embodiments, particular embodiments will be illustrated in the drawings and described in detail in the written description. However, this is not intended to limit the inventive concept to particular modes of practice, and it is to be appreciated that all changes, equivalents, and substitutes that do not depart from the spirit and technical scope are encompassed in the inventive concept. Like reference numerals in the drawings generally denote like elements. As used herein, the term “and/or” includes any and all combinations of one or more of the associated listed items. Expressions such as “at least one of,” when preceding a list of elements, modify the entire list of elements and do not modify the individual elements of the list.

While such terms as “first,” “second,” and the like may be used to describe various components, such components must not be limited to the above terms. The above terms are used only to distinguish one component from another.

The terms used in the present specification are merely used to describe particular embodiments, and are not intended to limit the inventive concept. An expression used in the singular encompasses the expression of the plural, unless it has a clearly different meaning in the context. In the present specification, it is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Reference will now be made in detail to embodiments, examples of which are illustrated in the accompanying drawings.

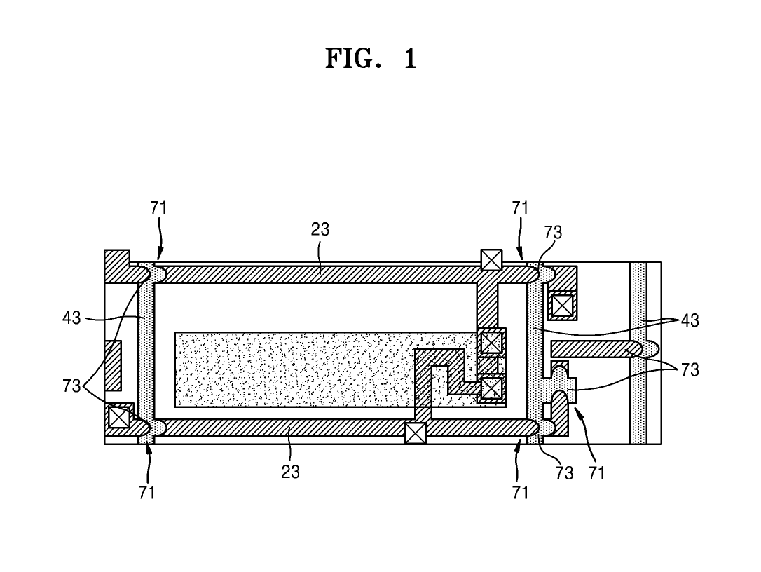

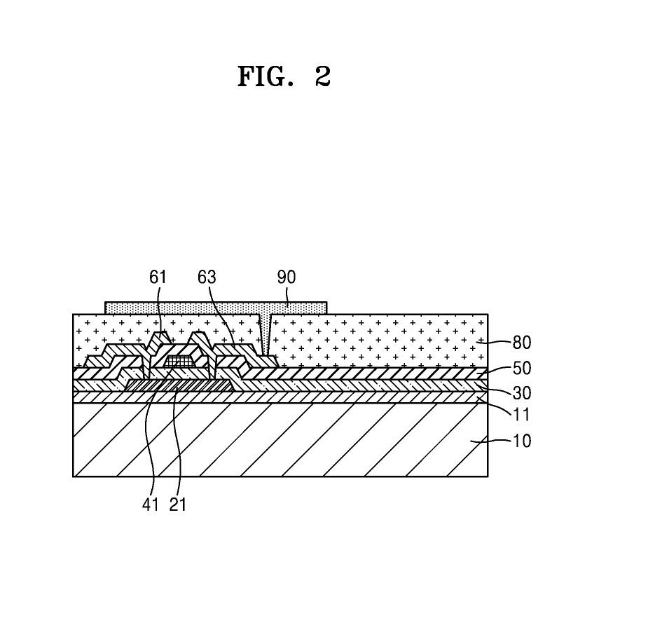

FIG. 1 is a schematic wiring diagram according to an embodiment. FIG. 2 is a schematic cross-sectional view of a thin film transistor (TFT) according to an embodiment.

As shown in FIGS. 1 and 2, the TFT according to an embodiment may include a buffer layer 11 that is formed on a substrate 10.

An active pattern (21, 23) may be formed on the buffer layer 11. The active pattern may include an active layer 21 and an active line 23.

Functions of the buffer layer 11 include blocking impurities and planarizing a surface of the substrate 10. The buffer layer 11 may include various materials to perform these functions. For example, the buffer layer 11 may be formed as a single layer including an inorganic material, such as, for example, silicon oxide, silicon nitride, silicon oxynitride, aluminum oxide, aluminum nitride, titanium oxide, or titanium nitride, an organic material, such as, for example, polyimide, polyester, or acryl, or multiple layers of these materials. The buffer layer 11 is not an essential element and may be omitted in some embodiments.

The active layer 21 may include polycrystalline silicon. However, embodiments are not limited thereto, and the active layer 21 may also include an oxide semiconductor. If the active layer 21 includes an oxide semiconductor, light transmission rate may be increased in a pixel region, and thus, an overall external light transmission rate of a display unit may be increased. The active layer 21 may include a channel area that is not doped with impurities, and a source area and a drain area that are doped with impurities at both sides of the channel area. The impurities may vary according to a type of the TFT and may be N-type impurities pr P-type impurities.

The TFT may include a gate insulating layer 30 that is formed on the buffer layer 11 to cover the active layer 21, and a gate pattern (41, 43) on the gate insulating layer 30.

The gate insulating layer 30 may be formed as a single layer or multiple layers including an inorganic material such as, for example, silicon oxide or silicon nitride. The gate insulating layer 30 may insulate the active layer 21 from the gate pattern (41, 43).

The gate pattern may include a gate electrode 41 and a gate line 43.

An interlayer insulating layer 50 may be formed on the gate insulating layer 30 to cover the gate electrode 41. A source electrode 61 and a drain electrode 63 may be formed on the interlayer insulating layer 50 and contact the active layer 21 via contact holes.

A structure of the TFT is not limited to that shown in the drawings, and various structures may be used.

As shown in FIG. 2, the source and drain electrodes 61 and 63 of the TFT are formed at a level different from the active layer 21. However, the embodiments are not limited thereto, and at least one selected from the source and drain electrodes 61 and 63 of the TFT may be formed at the same level as the active layer 21.

As shown in FIG. 1, the TFT may further include a channel area 71 that is formed in an area where the gate line 43 and the active line 23 overlap each other.

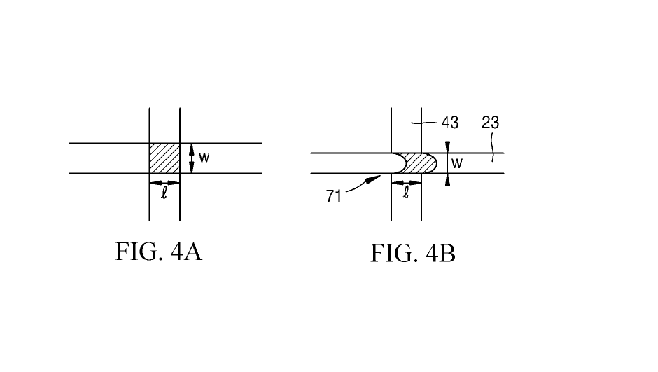

The channel area 71 functions as an area where current flows. If a width w (see FIG. 4) of the channel area 71 is large, a large amount of on-current (Ion) may flow therethrough.

The on-current (Ion) is a unique value that is set when the TFT is manufactured and refers to a minimum current that flows when the TFT is on.

That is, as a value of the on-current (Ion) is larger, a value of current that flows when the TFT is driven is also larger. The value of on-current (Ion) is proportionate to the width w of the channel area 71.

As shown in FIG. 1, the width w of the channel area 71 may be determined by a width of the active line 23, and a length 1 of the channel area 71 may be determined by a width of the gate line 43.

That is, the width w of the channel area 71 may be determined according to respective widths of the active line 23 and the gate line 43. Since the width w of the channel area 71 is proportionate to an amount of current that may flow through the channel area 71, as the width w of the channel area 71 is increased, a larger amount of current may flow through the channel area 71. As a result, the on-current (Ion) may be increased.

As shown in FIG. 1, the TFT may further include a gate line modifying unit 73 that is formed by changing a linear shape of the gate line 43 in the channel area 71.

A gate line or an active line that is generally used in the TFT may have a linear shape in the form of an “I.” In this case, a channel area may have a rectangular shape.

However, if the gate line modifying unit 73 is formed by changing a linear shape of the channel area 71 to a different shape as shown in FIG. 1, a length of a portion of the gate line 43 which overlaps the active line 23 is increased, and thus, the width w of the channel area 71 may be increased.

That is, the width w of the channel area 71 may be increased without a change in a width of the active line 23 or a width of the gate line 43, and thus, the on-current (Ion) that flows through the channel area 71 may be increased.

As shown in FIG. 1, in the TFT, the channel area 71 may be formed by changing the linear shape of the gate line 43. Specifically, the gate line modifying unit 73 may have a “U” shape.

In this case, the gate line 43 may be formed as a curve in the channel area 71, and accordingly, the width w of the channel area 71 may be increased. Therefore, the on-current (Ion) may be increased.

The shape of the gate line 43 is not limited to the “U” shape, and the gate line 43 may be changed to any shape that may increase the width w of the channel area 71.

As shown in FIG. 2, the TFT may further include a protection layer 80 formed on the source and drain electrodes 61 and 63, and a pixel electrode 90 formed at an upper portion of the protection layer 80.

The protection layer 80 may be a single insulating layer or multiple insulating layers having a planarized upper surface. The protection layer 80 may be formed by using an inorganic material and/or an organic material. For example, the protection layer 80 may be formed as a single layer or multiple layers including an inorganic material, an organic material, or a combination thereof by using various deposition methods. According to some embodiments, the protection layer 80 may be formed by using at least one of polyacrylates resin, epoxy resin, phenolic resin, polyamides resin, polyimides resin, unsaturated polyesters resin, poly(phenylenethers) resin, poly(phenylenesulfides) resin, and benzocyclobutene (BCB).

The protection layer 80 may cover both the pixel region and a transmission region.

The pixel electrode 90 may be provided at the upper portion of the protection layer 80 and electrically connected to the drain electrode 63 via a contact hole. The pixel electrode 90 may be formed to have an island shape that is separated according to sub-pixels. The pixel electrode 90 may be disposed not to overlap a pixel circuit unit.

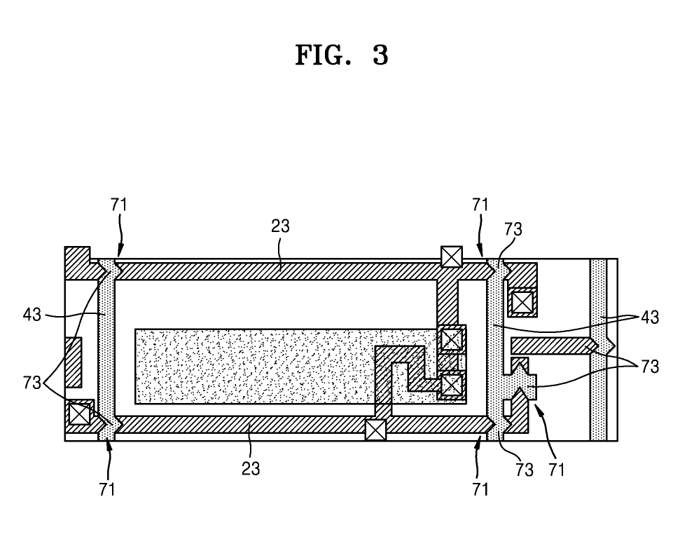

FIG. 3 is a schematic wiring diagram of a TFT according to an embodiment.

The TFT may include the gate line modifying unit 73 that is formed by changing the linear shape of the gate line 43 in the channel area 71. Specifically, the gate line modifying unit 73 may be changed to have a “V” shape.

In this case, since the gate line 43 has a protruding shape rather than the linear shape in the channel area 71, the width w of the channel area 71 may be increased without a change in the width of the active line 23. Thus, the on-current (Ion) may be increased.

As described above, the shape of the gate line 43 is not limited to the “V” shape, and the gate line 43 may be changed to any shape that may increase the width w of the channel area 71.

The TFT may include the gate line modifying unit 73 having a shape other than the linear shape in the channel area 71. In addition, the gate line modifying unit 73 may be provided at an end of the gate line 43.

That is, although FIG. 3 illustrates only a portion of the gate line 43, with regard to the entire substrate, the gate line modifying unit 73 may be provided at an end of the substrate as in FIG. 3.

FIG. 4A is a schematic expanded diagram of a channel area of the related art, and FIG. 4B is a schematic expanded diagram of the channel area 71 according to another embodiment.

The TFT may include the gate line modifying unit 73 that has a shape other than the linear shape in the channel area 71, and thus a width of the active line 23 may be small. Therefore, an opening rate may be increased.

That is, in the TFT, since the gate line modifying unit 73 is formed in the channel area 71, the width of the active line 23 may be small.

In this case, even when the shape of the gate line 43 is changed, the width w of the channel area 71 may have the same value as that when the gate line 43 has the linear shape in the channel area 71. That is, the width of the active line 23 may be reduced such that the on-current (Ion) is not reduced.

As a result, since the gate line modifying unit 73 is formed in the channel area 71, the width w of the channel area 71 may be maintained constant even if the width of the active line 23 is reduced by a small amount.

Therefore, the TFT include the gate line modifying unit 73 that is formed by changing the shape of the gate line 43 to a shape other than the linear shape in the channel area 71, and simultaneously, the width of the active line 23 may be reduced. Therefore, since the width of the active line 23 is reduced, a circuit area is reduced in size, and thus, an opening rate may be increased.

That is, since a size of the channel area 71 is maintained in uniform in the TFT, the on-current (Ion) is not reduced while the width of the active line 23 is reduced, and thus, an opening rate may be increased.

The width of the active line 23 may be reduced such that a size of the channel area 71 may be the same as when the gate line 43 has a linear shape, as described above. However, the width of the active line 23 is not limited thereto.

That is, as long as the gate line 43 includes the gate line modifying unit 73 at the channel area 71, if the width of the active line 23 is reduced by a certain amount, the on-current (Ion) is increased and the opening rate may be increased.

As described above, according to the one or more embodiments, an on-current may be increased by increasing a width of a channel area without increasing a size of an active wiring or a size of a gate wiring.

It should be understood that the embodiments described herein should be considered in a descriptive sense only and not for purposes of limitation. Descriptions of features or aspects within each embodiment should be considered as available for other similar features or aspects in other embodiments.

While one or more embodiments have been described with reference to the appended figures, it will be understood by those of ordinary skill in the art that various changes in form and details may be made therein without departing from the spirit and scope as defined by the following claims.

What is claimed is:

1. A thin film transistor (TFT) comprising:
an active pattern formed on a substrate;
a gate pattern formed on the active pattern and comprising a gate electrode and a gate line;
a gate insulating layer disposed between the gate pattern and the active pattern;
a source electrode that overlaps a first side of the active pattern and contacts a data line;
a drain electrode that overlaps a second side of the active pattern and is separated from the source electrode;
a channel area formed in an area where the gate line and an active line of the active pattern overlap each other; and
a gate line modifying unit formed in the channel area by changing a linear shape of the gate line.

2. The TFT of claim 1, further comprising a protection layer formed on the source and drain electrodes.

3. The TFT of claim 2, further comprising a pixel electrode formed in an upper portion of the protection layer and contacting the drain electrode via a contact hole.

4. The TFT of claim 1, wherein the gate line modifying unit has a “U” shape.

5. The TFT of claim 1, wherein the gate line modifying unit has a “V” shape.

6. The TFT of claim 1, wherein a width of the active line is reduced such that a size of the channel area is the same as a gate line having a linear shape.

7. A method of manufacturing a thin film transistor, the method comprising:
forming an active pattern on a substrate, the active pattern comprising an active layer and an active line;
depositing a gate insulating layer on the active pattern; and
forming a gate pattern on the gate insulating layer, the gate pattern comprising a gate electrode and a gate line;
wherein a channel area is formed at an area where the gate line and the active line overlap each other, and
a gate line modifying unit is formed by changing a linear shape of the gate line at the channel area.

8. The method of claim 7, wherein the gate line modifying unit has a “U” shape.

9. The method of claim 7, wherein the gate line modifying unit has a “V” shape.

10. The method of claim 7, further comprising forming a source electrode that overlaps a first side of the active pattern and contacts a data line.

11. The method of claim 10, further comprising forming a drain electrode that overlaps a second side of the active pattern and is separated from the source electrode;

12. The method of claim 11, further comprising forming a protection layer on the source and drain electrodes.

13. The method of claim 12, further comprising forming a pixel electrode formed in an upper portion of the protection layer and contacting the drain electrode via a contact hole.

14. The method of claim 7, wherein a width of the active line is reduced such that a size of the channel area is the same as a gate line having a linear shape.

15. A thin film transistor (TFT) comprising:
an active pattern formed on a substrate;
a gate pattern formed on the active pattern and comprising a gate electrode and a gate line;
a gate insulating layer disposed between the gate pattern and the active pattern;
a channel area formed in an area where the gate line and the active line overlap each other; and
a gate line modifying unit formed in the channel area by changing a linear shape of the gate line.

16. The TFT of claim 15, wherein the gate line modifying unit has a “U” shape.

17. The TFT of claim 15, wherein the gate line modifying unit has a “V” shape.

18. The TFT of claim 15, wherein a width of the active line is reduced such that a size of the channel area is the same as a gate line having a linear shape.

19. The TFT of claim 15, further comprising:
a source electrode that overlaps a first side of the active pattern and contacts a data line; and
a drain electrode that overlaps a second side of the active pattern and is separated from the source electrode.

20. The TFT of claim 19, further comprising:
a protection layer formed on the source and drain electrodes; and
a pixel electrode formed in an upper portion of the protection layer and contacting the drain electrode via a contact hole.
